(19) United States
(12) Patent Application Publication
(10) Pub. No.: US 2007/0295971 A1
(43) Pub. Date: Dec. 27, 2007

(54) Light Emitting Device and Method for Fabricating the Same

(76) Inventor: Hee Jin Kim, Gwangsan-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/762,585

(22) Filed: Jun. 13, 2007

(30) Foreign Application Priority Data
Jun. 13, 2006 (KR) 10-2006-0053191

(51) Int. Cl. H01L 33/00

(52) U.S. Cl. 257/79

(57) ABSTRACT

Disclosed are a light emitting device and a method for fabricating the same. The light emitting device can include a substrate, a buffer layer having a pattern on the substrate, a first conductive-type semiconductor layer on the buffer layer, an active layer on the first conductive-type semiconductor layer, and a second conductive-type semiconductor layer on the active layer.

### CROSS-REFERENCE TO RELATED APPLICATION

The present application claims the benefit under 35 U.S.C. § 119 of Korean Patent Application No. 10-2006-0053191, filed Jun. 13, 2006, which is hereby incorporated by reference in its entirety.

### BACKGROUND

A light emitting diode (LED) is a representative light emitting device. The light emitting diode converts an electrical signal into light using the characteristic of a compound semiconductor. The light emitting diode includes an N-type semiconductor layer, an active layer, and a P-type semiconductor layer, which are stacked such that light generated from the active layer can be emitted to an exterior when power is applied thereto.

### BRIEF SUMMARY

Embodiments of the present invention can provide a light emitting device and a method for fabricating the same, capable of improving the light emitting efficiency.

An embodiment provides a light emitting device including a substrate, a buffer layer having a pattern formed thereon on the substrate, a first conductive-type semiconductor layer on the buffer layer, an active layer on the first conductive-type semiconductor layer, and a second conductive-type semiconductor layer on the active layer.

In an embodiment, there is provided a light emitting device including a substrate, a buffer layer on the substrate where the buffer layer has a thickness in a range of 5 μm to 15 μm, a first conductive-type semiconductor layer on the buffer layer, an active layer on the first conductive-type semiconductor layer, and a second conductive-type semiconductor layer on the active layer.

In an embodiment, there is provided a method for fabricating a light emitting device. The method can include preparing a substrate, forming a buffer layer having a thickness in a range of 5 μm to 15 μm on the substrate, forming a first conductive-type semiconductor layer on the buffer layer, forming an active layer on the first conductive-type semiconductor layer, and forming a second conductive-type semiconductor layer on the active layer.

### BRIEF DESCRIPTION OF THE DRAWINGS

FIG. 1 is a cross-sectional view showing a structure of a light emitting device according to an embodiment;

FIG. 2 is a flowchart showing a manufacturing process of a light emitting device according to an embodiment;

FIG. 3 is a perspective view showing a pattern formed on a buffer layer of a light emitting device according to an embodiment; and

FIG. 4 is a perspective view showing patterns formed on a buffer layer of a light emitting device according to an embodiment.

### DETAILED DESCRIPTION

Hereinafter, embodiments of a light emitting device and a method for fabricating the same will be described in detail with reference to the accompanying drawings.

In the following description, the expression “formed on/under a predetermined element” may include the meaning of both “formed directly on/under the element” and “formed indirectly on/under the element by interposing other element therebetween”.

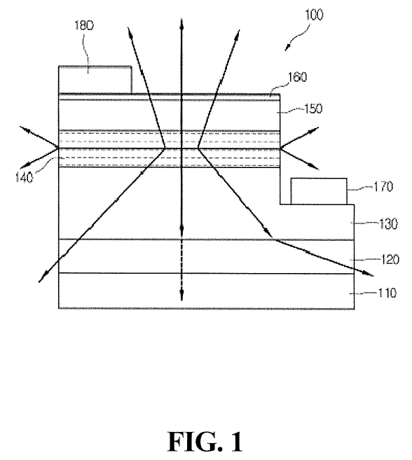

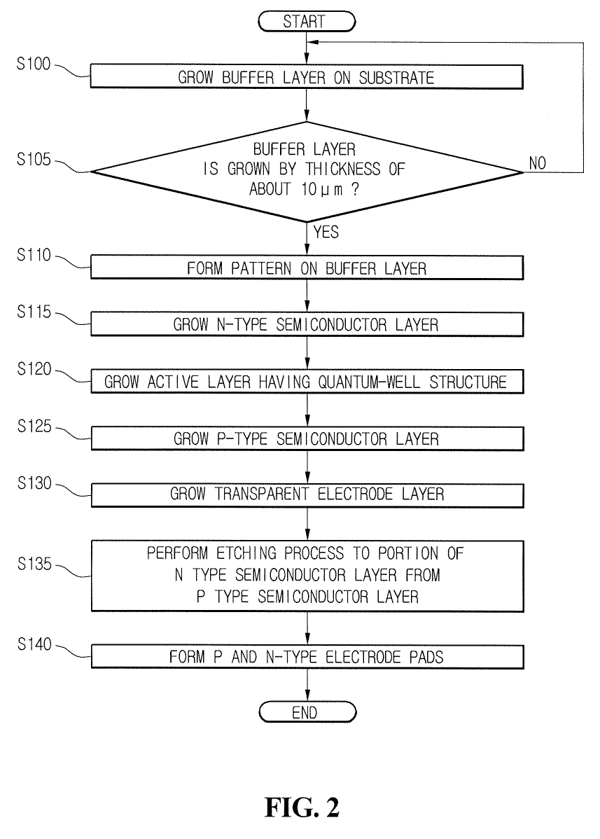

FIG. 1 is a cross-sectional view showing the structure of a light emitting device 100 according to an embodiment, and FIG. 2 is a flowchart showing a manufacturing process of the light emitting device 100 according to an embodiment.

Referring to FIGS. 1 and 2, the light emitting device 100 according to an embodiment includes a substrate 110, a buffer layer 120, a first conductive-type semiconductor layer 130, an active layer 140, a second conductive-type semiconductor layer 150, a transparent electrode layer 160, a first electrode layer 170, and a second electrode layer 180.

The buffer layer 120 can be formed with a pattern, and has a thickness sufficient to form the pattern.

The substrate 110 can be a substrate formed of at least one material including sapphire (Al₂O₃), silicon (Si), silicon carbide (SiC), gallium arsenide (GaAs), zinc oxide (ZnO), and magnesium oxide (MgO). In one embodiment, the substrate 110 can be a sapphire substrate.

The substrate 110 can be fixed onto a susceptor prepared in a reaction tube for metal organic chemical vapor deposition (i.e., an MOCVD reaction tube) under a low pressure after a cleaning process.

In an embodiment, once air is sufficiently removed from the MOCVD reaction tube, the substrate 110 can be heated with the temperature of 1090° C. for about ten minutes while hydrogen gas is being supplied into the MOCVD reaction tube to remove an oxide layer from the surface of the substrate 110.

Then, after lowering the temperature of the substrate 110 up to about 525° C., hydrogen gas and ammonia gas having the flow rate of 8 liter/min can be supplied into the MOCVD reaction tube, such that the substrate 110 is stabilized with the temperature of 520° C.

Upon stabilizing the substrate 110 with the temperature of 520° C., trimethylgallium (TMGa) and trimethylindium (TMIn) having the flow rate of 3×10⁵ mol/min and trimethylaluminum (TMAl) having the flow rate of 3×10⁶ mol/min can be injected into the MOCVD reaction tube together with the hydrogen gas and the ammonia gas to grow the buffer layer 120 (step S100).

The buffer layer 120 can prevent the substrate 110 from being subject to melt-back etching caused by the chemical action of the substrate 110. In an embodiment, the buffer layer 120 can be grown to have a thickness in the range of 5 μm to 15 μm. In an embodiment, the buffer layer 120 can be grown to have a thickness of about 10 μm (step S105).

Although buffer layers of most light emitting devices are very thin, the buffer layer 120 according to an embodiment can be grown to a sufficient thickness such that a pattern can be formed on the buffer layer 120. In an embodiment, the buffer layer 120 can be formed with the thickness in the range of 5 μm to 15 μm to increase the light emitting efficiency at the sides of the light emitting device.

The buffer layer 120 can be formed in a multi-layer having the stack structure of AlInN/GaN, InₓGa₁₋ₓN/GaN, and AlₓIn_{y}Ga_{1-x-y}N/InₓGa₁₋ₓN/GaN.

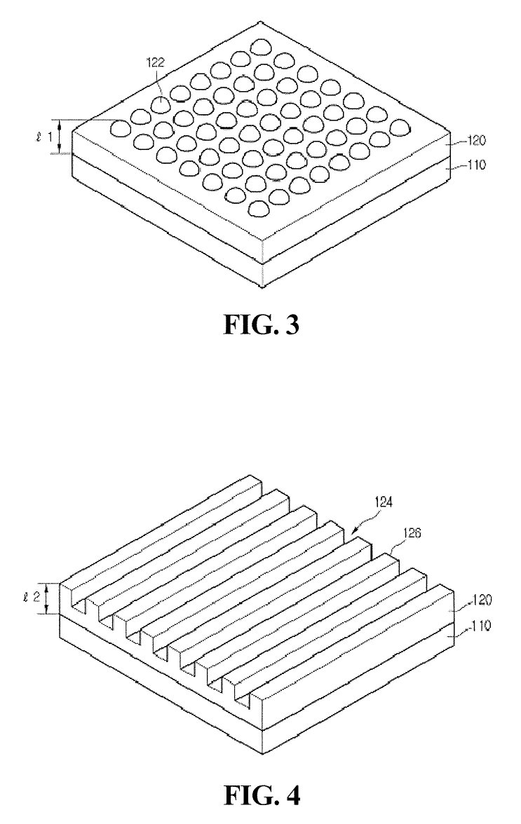

FIG. 3 is a perspective view showing a pattern 122 formed on a buffer layer 120 of a light emitting device 100 according to a first embodiment, and FIG. 4 is a perspective view showing patterns 124 and 126 formed on a buffer layer 120 of a light emitting device 100 according to a second embodiment.

In an embodiment, once the buffer layer 120 is formed to a desirable thickness, a pattern can be formed on the surface of the buffer layer 120 (step S110).

Referring to FIG. 3, in a first embodiment, the pattern 122 allows diffused reflection. In other words, the pattern 122 can be prepared in the form of a convex lens or a concave lens.

Referring to FIG. 4, in a second embodiment, the patterns 124 and 126 can have a convex-concave structure including a linear slot 124 and a linear protrusion 126.

Although the patterns having two shapes are representatively shown in FIGS. 3 and 4, the patterns may be variously formed.

In detail referring to the embodiments illustrated in FIGS. 3 and 4, the buffer layer 120 can have a flat bottom surface to make contact with the substrate 110 and a top surface including a flat surface 126 and a pattern 124 recessed from the flat surface or a pattern 122 protruding from the flat surface.

The patterns 122, 124, and 126 can be formed through an etching process using a photoresist. The etching process may be a dry etching process or a wet etching process.

In one embodiment, the etching process can be performed for about 20 minutes. If the buffer layer 120 is subject to a wet etching process, the buffer layer 120 can be etched at the same etching rate in vertical and horizontal directions due to the characteristic of an isotropic etching process. Accordingly, a desirable etching scheme can be selected according to the shape of the pattern.

The dry etching process may be physically performed by ion impact, or chemically performed by reactants generated from plasma. When patterns are formed through the dry etching process, a reactive ion etch (RIE) can be used.

According to an embodiment, the buffer layer 120 can be formed to a thick thickness and include patterns (e.g. 122, 124, 126), so that a portion of light downwardly irradiated may be transmitted toward the substrate 110, and most of the light may be emitted through the sides of the buffer layer 120 as marked by arrows of FIG. 1.

In other words, the thickness of the buffer layer 120 and the patterns (122,124, 126) allow light to be emitted through the sides of the buffer layer 120.

Referring back to FIG. 2, after raising the growth temperature up to about 1000° C., trimethylgallium (TMGa) having the flow rate of 7×10⁵ mol/min can be injected into the MOCVD reaction tube together with the hydrogen gas and the ammonia gas to grow an undoped gallium nitride (GaN). Subsequently, silane (SiH₄) gas can be introduced into the MOCVD reaction tube at the flow rate of 7×10⁹ mol/min to form the first conductive-type semiconductor layer 130 (step S115).

In one embodiment, the first conductive-type semiconductor layer 130 can be an N-type semiconductor layer.

As the first conductive-type semiconductor layer 130 is formed, the growth temperature can be lowered to about 700° C., and the active layer 140 having a quantum-well structure can be grown under the nitrogen atmosphere while injecting trimethylgallium (TMGa) and trimethylindium (TMIn) into the MOCVD reaction tube (step S120).

Then, the second conductive-type semiconductor layer 150 can be grown on the active layer 140 (step S125).

In one embodiment, the second conductive-type semiconductor layer 150 can be a P-type semiconductor layer.

The second conductive-type semiconductor layer 150 can be formed by raising the growth temperature up to 1010° C. and introducing trimethylgallium (TMGa) and bis(cyclopentadienyl)magnesium (Cp₂Mg).

The second conductive-type semiconductor layer 150 can include a group III/V nitride semiconductor similar to the first conductive-type semiconductor layer 130. In operation, when the first conductive-type semiconductor layer 130 is N-type and the second conductive-type semiconductor layer 150 is P-type, light can be emitted when holes of the second conductive-type semiconductor layer 150 combine with electrons of the first conductive-type semiconductor layer 130 in the active layer 140.

The active layer 140 can be grown through various schemes such as a metal organic chemical vapor deposition scheme.

Hereinafter, details will be described regarding the growing process of the active layer 140 according to embodiments. A deposition process can be performed while forming grains in a first stage. Then, as the grains are fused during the deposition process, the grains are enlarged, thereby forming nano-holes having a predetermined size. After the nano-holes having a desirable size are grown, the nano-holes are filled with quantum material to form quantum dots. The quantum material used to form the quantum dots can include indium gallium nitride (InGaN), indium gallium arsenide InGaAs), and indium gallium phosphide (InGaP).

The transparent electrode layer 160 can be formed on the second conductive-type semiconductor layer 150 (step S130). The transparent electrode layer 160 can be formed of indium-tin-oxide (ITO), which has superior light transmittance and increases current diffusion. Thereafter, an etching process is performed in order to form the first electrode layer 170 (step S135).

Layers from the transparent electrode layer 160 to a portion of the first conductive-type semiconductor layer 130 can be etched away, and the first electrode layer 170 can be deposited on the first conductive type semiconductor layer 130.

The deposition schemes of the first electrode layer 170 can include an atmospheric pressure chemical vapor deposition (APCVD) scheme, a low pressure chemical vapor deposition (LPCVD) scheme, a plasma enhanced chemical vapor deposition (PECVD) scheme, and a metal thin film deposition using copper (Co) or aluminum (Al) having the high degree of purity.

Then, the second electrode layer 180 can be formed on the transparent electrode layer 160 similar to the first electrode layer 170 (step S140).

Accordingly, the light emitting device 100 according to an embodiment may be completely fabricated.

In the light emitting device 100 according to an embodiment, light downwardly irradiated from the active layer 140 is emitted through the sides of the buffer layer 120, thereby minimizing an amount of light extinguished in the light emitting device 100.

Accordingly, the light emitting efficiency of the light emitting device 100 can be maximized.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device comprising:
a substrate;
a buffer layer on the substrate, wherein the buffer layer has a pattern;
a first conductive-type semiconductor layer on the buffer layer;
an active layer on the first conductive-type semiconductor layer; and
a second conductive-type semiconductor layer on the active layer.

2. The light emitting device according to claim 1, wherein the buffer layer has a thickness in a range of 5 μm to 15 μm.

3. The light emitting device according to claim 1, wherein the pattern comprises a convexly curved surface or a concavely curved surface.

4. The light emitting device according to claim 1, wherein the pattern comprises a linear slot and a linear protrusion.

5. The light emitting device according to claim 1, further comprising a first electrode layer formed on the first conductive-type semiconductor layer, and a second electrode layer formed on the second conductive-type semiconductor layer.

6. A light emitting device comprising:
a substrate;
a buffer layer on the substrate, wherein the buffer layer has a thickness in a range of 5 μm to 15 μm;
a first conductive-type semiconductor layer on the buffer layer;
an active layer on the first conductive-type semiconductor layer; and
a second conductive-type semiconductor layer on the active layer.

7. The light emitting device according to claim 6, wherein the buffer layer has a recessed or protruding pattern formed thereon.

8. The light emitting device according to claim 7, wherein the pattern comprises a convexly curved surface or a concavely curved surface.

9. The light emitting device according to claim 7, wherein the pattern comprises a linear slot and a linear protrusion.

10. The light emitting device according to claim 6, wherein the buffer layer has a flat bottom surface and a top surface including a flat surface and a pattern protruding from the flat surface or recessed from the flat surface.

11. The light emitting device according to claim 6, further comprising a first electrode layer formed on the first conductive-type semiconductor, and a second electrode layer formed on the second conductive-type semiconductor layer.

12. A method for fabricating a light emitting device, the method comprising:
preparing a substrate;
forming a buffer layer to a thickness in a range of 5 μm to 15 μm on the substrate;
forming a first conductive-type semiconductor layer on the buffer layer;
forming an active layer on the first conductive-type semiconductor layer; and
forming a second conductive-type semiconductor layer on the active layer.

13. The method according to claim 11, further comprising forming a pattern on a top surface of the buffer layer after forming the buffer layer.

14. The method according to claim 12, wherein the pattern comprises a convexly curved surface or a concavely curved surface.

15. The method according to claim 12, wherein the pattern comprises a linear slot and a linear protrusion.

16. The method according to claim 12, wherein forming the pattern comprises etching a portion of the buffer layer.

17. The method according to claim 11, wherein the buffer layer has a flat bottom surface and a top surface including a flat surface and a pattern protruding from the flat surface or recessed from the flat surface.

18. The method according to claim 11, further comprising forming a first electrode layer on the first conductive-type semiconductor layer, and forming a second electrode layer on the second conductive-type semiconductor layer.
